(19) United States
(12) Patent Application Publication
(10) Pub. No.: US 2021/0265520 A1
(43) Pub. Date: Aug. 26, 2021

(54) A PHOTODETECTOR

(71) Applicant: Cambridge Enterprise Limited, Cambridgeshire (GB)

(72) Inventors: Matthew Applegate, Cambridgeshire (GB); Andrew Irvine, Cambridgeshire (GB); Crispin Barnes, Cambridgeshire (GB)

(21) Appl. No.: 17/260,912

(22) PCT Filed: Jul. 16, 2019
(86) PCT No.: PCT/GB2019/051977

§ 371 Date: Jan. 15, 2021

(30) Foreign Application Priority Data
Jul. 17, 2018 (GB) 1811693.9

(51) Int. Cl. H01L 31/107; H01L 31/0224; H01L 31/0232; H01L 31/18

(52) U.S. Cl. CPC H01L 31/107; H01L 31/18; H01L 31/02327; H01L 31/022408

(57) ABSTRACT

We disclose herein a photodetector comprising at least one absorption region in which photons are absorbed; and a plurality of electrodes disposed on the at least one absorption region, the electrodes being spaced apart from one another. In use, the geometry of at least one electrode is chosen to enhance the formation of an electric field of the requisite magnitude for avalanche multiplication to occur near the at least one electrode.

### TECHNICAL FIELD

The present disclosure relates to a photodetector.

### BACKGROUND

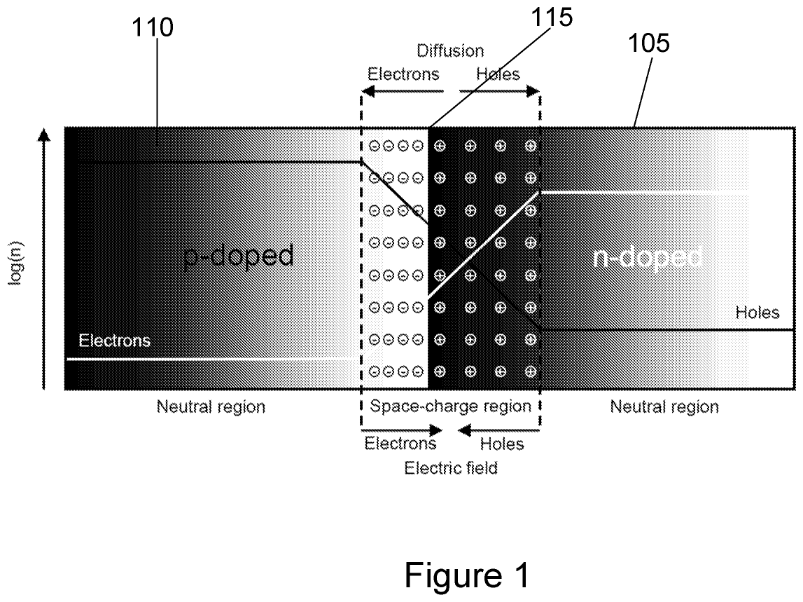

Photodiodes are semiconductor photodetectors that utilise the internal photoelectric effect and are based on p-n junctions at which an inbuilt electric field is formed that is exploited for photo detection. The basic device structure is shown in FIG. 1, but may involve many more layers than those depicted. As seen, there is an n-doped layer 105 and a p-doped layer 110, at the interface between which (the p-n junction 115) an inbuilt electric field is established that is augmented with an applied reverse bias.

It is known that p-i-n photodiodes are the most commonly employed photodiodes. Unfortunately, the intrinsic amplification of photocurrent required for low-level light detection down to the quantum limit (single-photon detection) is very difficult to achieve with p-i-n photodiodes simply because of their structure. The intrinsic layer sandwiched between the p-doped and n-doped layers reduces the inbuilt field, leading to a very high breakdown voltage.

It is also known that a form of heavily-doped photodiode referred to as an avalanche photodiode (APD) boasts a substantial inbuilt field, resulting in a comparatively low breakdown voltage when compared to the p-i-n photodiode, and can be more readily rendered single-photon sensitive by operation in the Geiger mode where a reverse bias is applied to augment the inbuilt field to the critical level required for avalanche multiplication to occur—thereby providing the intrinsic amplification of photocurrent for low-level light detection down to the quantum limit.

In the present state of the art, photodiodes typically have numerous layers which increase both their cost and the complexity of their fabrication. Additionally, the crystalline defects that form at the junctions between the layers increase the likelihood of charge carriers recombining or becoming trapped, which reduces their responsivity and limits their efficiency. Furthermore, the high doping concentrations required for APDs result in an elevated capacitance—thereby limiting bandwidth.

In the prior art, it is also known that photoconductors (e.g. the metal-semiconductor-metal (MSM) photodetector) are photodetectors that utilise the internal photoelectric effect yet are not based on p-n junctions. Photoconductors are instead based on exploiting for photo detection the electric field established in bulk material by the direct application of an external bias. Compared to photodiodes, photoconductors have historically suffered from comparatively low responsivities, and have not been demonstrated to offer the intrinsic amplification of photocurrent required for low-level light detection down to the quantum limit.

### SUMMARY

Broadly speaking, the present disclosure relates to an electronic device comprising a plurality of electrodes disposed on a material, the geometry of the electrodes and the separation between the electrodes are optimised (or selected or chosen) in such a way as to establish an enhanced electric field in the material to optimise photon absorption, and to both maximise and amplify the resulting photocurrent.

According to one aspect of the present disclosure, there is provided a photodetector comprising at least one absorption region in which photons are absorbed; and a plurality of electrodes disposed on the at least one absorption region, the electrodes being spaced apart from one another. In use, a geometry of at least one electrode of the plurality of electrodes is chosen (or selected or optimised) to enhance the formation of an electric field of the requisite magnitude for avalanche multiplication to occur near the at least one electrode. It will be understood that the requisite electric field magnitude for avalanche multiplication occurs at a given material's breakdown voltage.

The at least one absorption region may comprise a predetermined material, and the avalanche multiplication takes places in the predetermined material (near or in proximity to the electrodes). The avalanche multiplication may take places near a surface between the at least one electrode (or the electrodes) and the at least one absorption region (within the predetermined material). It will be understood that the at least one absorption region (or layer) includes a predetermined material specifically selected to absorb incident photons of a desired wavelength or range of wavelengths, and comprises at least one region near its interface with an electrode in which the avalanche multiplication takes place.

Generally speaking, the absorption region is a contact region made of the predetermined material. The electrodes or contacts are formed on the predetermined material. The material of the contact region is an intrinsic (un-doped) material, or it may be a material in which doping or the inclusion of a region of heterogeneous material is used to compensate carriers in the predetermined material or to repel carriers from it. In other words, the contact region or the absorption region is made of a substantially (or almost) carrier-free material.

The at least one absorption region may comprise an avalanche region having no or a few carriers, and the avalanche multiplication may take place in the avalanche region. The shape and arrangement of the at least one electrode may be chosen to achieve the avalanche multiplication. A distance (or a separation) between at least two electrodes may be selected to achieve the avalanche multiplication. A curvature of the at least one electrode may be selected (or chosen) to achieve the avalanche multiplication. A relative curvature of the at least one electrode may be varied to achieve the avalanche multiplication. The relative curvature may be derived from a ratio of a distance between at least two electrodes and a radius value of the at least one electrode.

It will be understood that the term ‘geometry’ of the electrodes or of the device refers to the shape, topology, topography, curvature, and/or arrangement of the electrodes. It will be understood that in the present disclosure the geometrical arrangements are chosen to achieve the desired avalanche multiplication effect at a given breakdown voltage. The skilled person would understand that both the curvature of the electrodes and/or their separation define their geometry. It will also be understood by the skilled person that any one or more of the shape of the electrodes, arrangement of the electrodes, curvature of the electrodes, or distance (or separation) between electrodes contribute to the geometry of the device. The geometry of the electrodes is not limited to any specific one or all of these parameters—the geometry can be any one or any combination of these parameters.

Advantageously, the disclosed device inherently exploits geometry, rather than doping, to enhance the formation of an electric field of the requisite magnitude for avalanche breakdown to occur in a prescribed material: thereby providing the necessary amplification of current required for low-level light detection right down to the quantum limit (single-photon detection). In one example, such a single-photon sensitive device having surprisingly low breakdown voltage (e.g. less than 15V, preferably less than 10V) has not been reported in the landscape before.

In one example, surprisingly, unlike an APD, the disclosed device's avalanche region is located at the surface where the contacts or electrodes are formed and where the vast majority of photons are absorbed. Additionally, the disclosed device exhibits a substantial field surrounding the avalanche region that rapidly drives charge carriers into it. Resultantly, the significant loss of efficacy attributed both to the recombination and trapping of charge carriers as they drift to the avalanche region is comprehensively mitigated: thereby, in one example, maximising both the responsivity and detection efficiency resulting in a considerable reduction in the operational duration and/or optical power. Both a surface avalanche layer and a substantial driving field are impossible to achieve with doped semiconductors.

Advantageously, the disclosed device's planar structure yields a significantly reduced capacitance in comparison to the highly-doped p-n junction of an APD: thereby resulting in a considerably enhanced operational bandwidth. Combined, these properties facilitate high-rate and/or high-absorption-volume operation, at an arbitrarily small voltage. It will be appreciated that there are advantages for the disclosed device both for low-level light detection as well as single-photon detection. It will be understood that the disclosed device is not limited to any one of these applications only.

Generally speaking, by operating a material at or above its breakdown field—a method of operation referred to as Geiger mode operation—mobile charge carriers created by the internal photoelectric effect can gain enough kinetic energy from the electric field for collisions to be ionising: resulting in the creation of additional mobile charge carriers for which the process can repeat again. This mechanism, referred to as avalanche breakdown, is self-sustaining and produces a macroscopic mobilisation of charge from a single photon: resulting in a measurable detection signal. Advantageously, the disclosed device is capable of exhibiting an avalanche breakdown voltage (e.g. less than about 15 V) orders of magnitude lower than those of even the most heavily-doped avalanche photodiodes: thereby offering the tremendous prospect of a reduced operational voltage resulting in an enhanced capability for very-large scale integration, and an ultra-low-level of power consumption. Additionally, unlike the superconducting single-photon detectors, the disclosed device may be operated at room temperature, provided that thermally-activated generation of carriers is not a limiting factor.

Advantageously, the disclosed device's structure is compatible with a wide range of material systems, of a similarly wide range of properties. The many elemental and compound semiconductors are compatible candidates, allowing a mixture of speed, confinement, tailored wavelength, and with silicon, a link to both quantum and classical computers. Insulators or wide-gap semiconductors may also be used for the detection of shorter wavelengths. A suitable choice of wavelength provides a means of interaction with any optoelectronic device. Organic devices could also benefit from the simplicity of structure which may complement emerging fabrication technologies.

The disclosed device structure is highly versatile and can be tailored to many varied applications requiring only a modification to the device geometry. For instance, for photon number detection an array of devices may be spatially multiplexed onto a single chip. In addition, the disclosed device may be integrated with on-chip planar waveguides. Owing to its technological simplicity, it may also be fabricated or subsequently deposited in close proximity to a photon source, positioned directly above or below, or laterally adjacent.

The degree of electric field enhancement in proximity to an electrode sharply increases with its curvature. When a bias is applied between at least two electrodes, the electric field established in proximity to them is substantially augmented. In other words, when a bias may be applied between the at least two electrodes, the electric field may be enhanced in proximity to the at least two electrodes and the electric field is substantially (or almost) diminished in a region between the at least two electrodes. Generally speaking, for a given bias applied across the electrodes, an enhanced field in one region is compensated for by a diminishment field elsewhere, but it is important to stress that the magnitude of the diminished field will not be zero—meaning photon-induced carriers created in the diminished region will be still be driven to the enhanced regions as intended.

The avalanche multiplication may be achieved at a theoretical minimum bias voltage corresponding to the band-gap potential of the absorber material, generally less than about 15V, and more preferably well below about 10V for a typical semiconductor. The avalanche multiplication may take place at a room temperature.

The photodetector may be a single-photon photodetector.

The plurality of electrodes may be asymmetric. This may mean that one electrode may have a different curvature and/or shape and/or arrangement compared to another electrode.

At least some (or all) of the plurality of electrodes may be transparent electrodes. At least some (or all) of the plurality of electrodes may be recessed electrodes.

At least some (or all) of the plurality of electrodes may be deposited adjacent to an absorber surface which is oriented other than parallel to a principal plane of the absorption region. In another example, at least some of the plurality of electrodes may be deposited on an absorber surface which is oriented other than parallel to the principal plane of the absorption region.

Photons may be delivered to the detector via a waveguide. The photodetector device may be incorporated into a photonic crystal.

In one example, photons may be focused on to the detector by a lens, which may be formed on the detector.

At least one photon may be spectrally separated by a prism or grating, which may be formed on the detector, such as to be incident or not incident on one or more detector devices.

At least some (or all) of the plurality of electrodes may be connected to (external or integrated) control circuitry. The plurality of electrodes may comprise any one or more conducting materials, including metal, metal multilayers, polysilicon or other conducting semiconductor, and/or a layer or layers formed during the growth procedure of the absorption region (or the absorption layer).

The photodetector may comprise anti-reflection coatings or anti-reflection layers. These layers are advantageous as they prevent the reflection of photons from the device surface that would otherwise reduce the detection efficiency.

The photodetector may further comprise a buried reflective layer to reflect photons back into the absorption layer. The buried reflector layer (or stack) may be used to reflect photons which would otherwise not be detected.

The photodetector may further comprise a detection region in the absorption region in which absorbed photons may generate carriers that contribute to the detector current. The photodetector may also comprise a barrier layer underneath and/or above the detection region. The barrier layer may be a wider-gap barrier layer. Generally speaking, carriers that recombine will not contribute to the detector current by reaching the electrodes, and the time taken for carriers to reach the electrodes may limit bandwidth. However, in the present device, the use of insulating or highly carrier-depleted absorber material improves both; the scarcity of free carriers strongly inhibits recombination and reduces the screening effects that limits the electric field established in conductors and doped semiconductors, leading to higher drift velocity and thus faster transit and higher speed of operation.

The photodetector contacts or electrodes may be placed on the face of a surface step, or on a top surface adjacent to the step, in order to detect photons with a lateral component of incidence angle. This may include those emitted from lateral waveguides.

The dark current might be large enough that isolation of some kind is desirable. A way to achieve this would be to incorporate the wider-gap barrier layer below the detection region, minimising the bulk generation of carriers and/or blocking the progress of those carriers towards the surface. This may be improved further by mesa-etching the absorber such that as large an area as possible of the contacts lies on the barrier material. The removal by etching of a sacrificial buried layer, a thinning of the entire substrate, or using a free-standing thin film as the absorber may have a similar effect.

According to another aspect of the present disclosure, there is provided a method of manufacturing a photodetector, the method comprising: forming at least one absorption region in which photons are absorbed; depositing a plurality of electrodes disposed on the at least one absorption region. The plurality of electrodes are spaced apart from one another. The method further comprises choosing or selecting the geometry of at least one electrode of the plurality of electrodes to enhance the formation of an electric field of the requisite magnitude for avalanche multiplication to occur near the at least one electrode. The method may further comprise using a lithographic technique.

Advantageously, due to the minimal number of steps required for its fabrication, and for which the difficult and costly stages of ion implantation are not required, it is both far easier and less costly to manufacture than existing single-photon detecting technologies like the p-i-n photodiode and avalanche photodiode (APD). The processing is also compatible with the industry-standard complementary metal-oxide semiconductor (CMOS) process, in its fundamental form involving only a final metallisation stage.

Generally speaking, the disclosed device has the following advantages:
Strongly enhanced field
   Low breakdown voltage
A single layer
   Reduced false detection rate, where a trained person would understand that examples of false detections include dark detections and afterpulses
   Minimised fabrication cost
Minimal number of processing steps
   No ion implantation
   CMOS compatible
   Possible to place retrospectively on existing structures
Avalanche layer is also the absorption layer (unlike the conventional APD)
   Reduces likelihood charge carriers recombine or get trapped
   Both electrons and holes can initiate an avalanche
Avalanche layer is also the drift layer (unlike the APD)
   Reduces likelihood charge carriers recombine or get trapped
   Reduces the device response time
Planar structure
   Miniscule capacitance (ultrahigh bandwidth)
   Integrates with in-plane photonics

### BRIEF DESCRIPTION OF THE PREFERRED EMBODIMENTS

Some preferred embodiments of the disclosure will now be described by way of example only and with reference to the accompanying drawings, in which:

FIG. 1 illustrates a known photodiode;

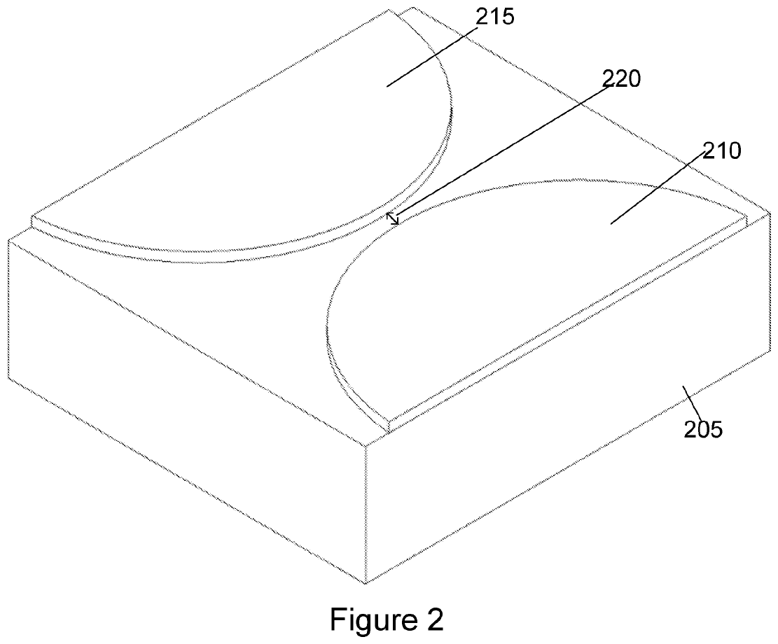

FIG. 2 illustrates a three-dimensional view of a photodetector according to one implementation;

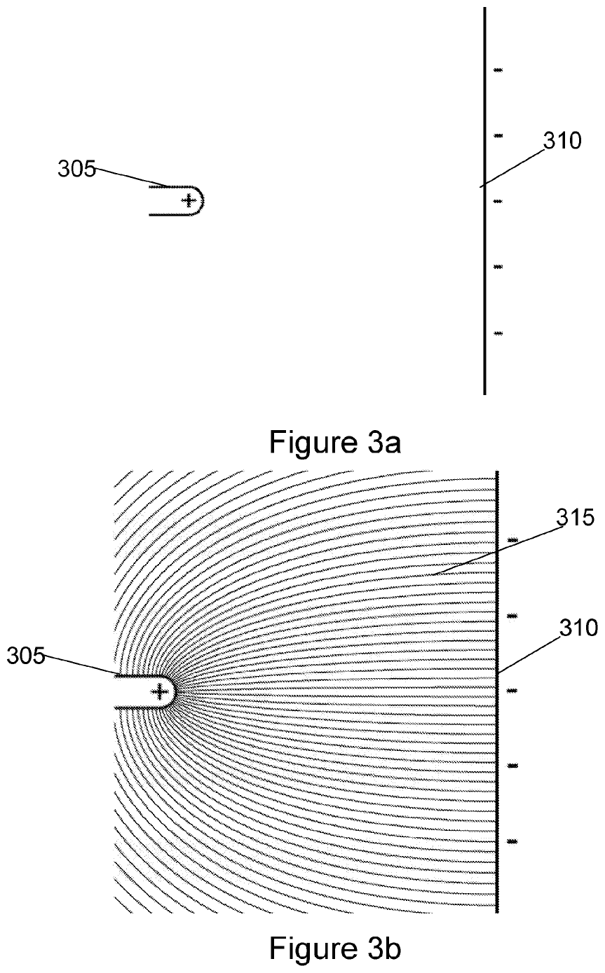

FIG. 3a illustrates a top view of an alternative photodetector according to one implementation. FIG. 3b illustrates a top view of the photodetector of FIG. 3a in which electric field line distribution between two electrodes is shown;

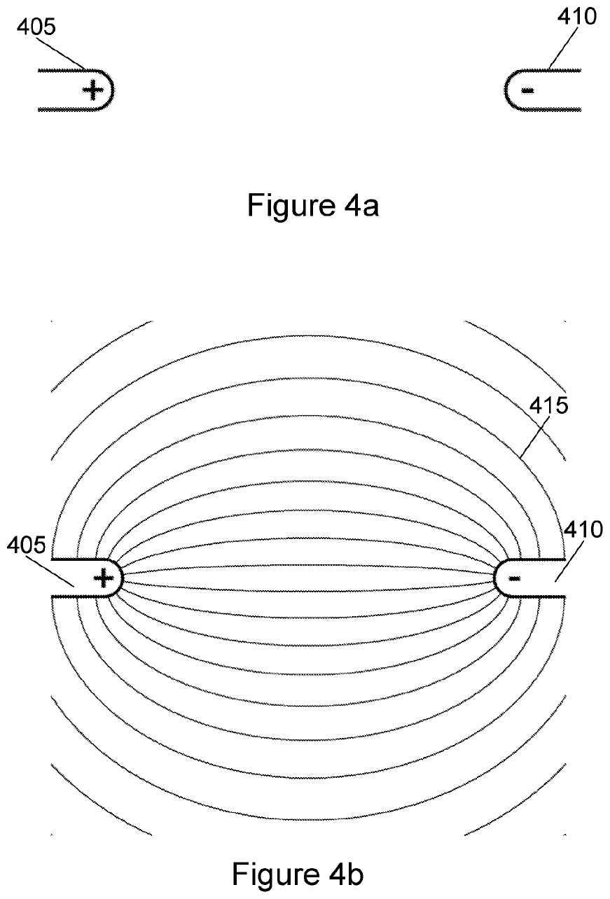

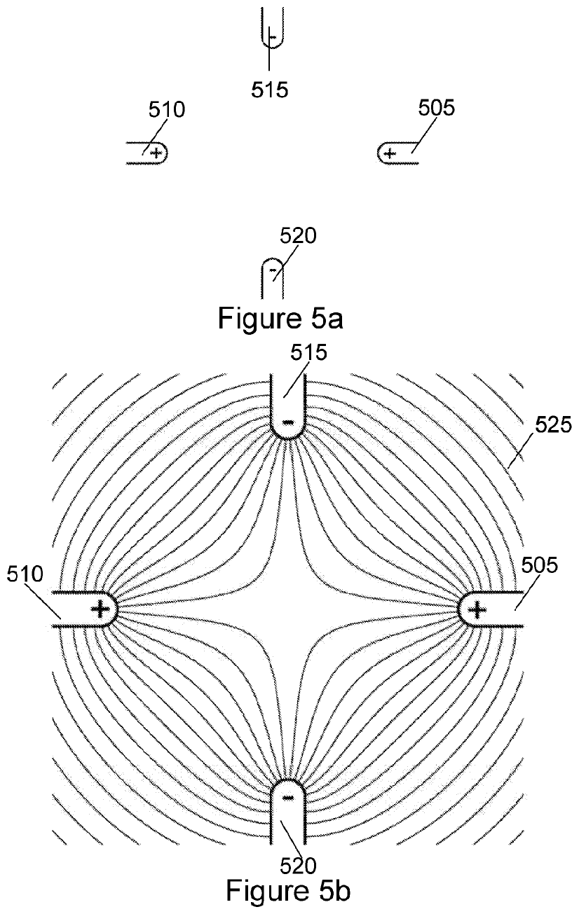

FIG. 4a illustrates a top view of an alternative photodetector according to one implementation. FIG. 4b illustrates a top view of the photodetector of FIG. 4a in which the electric field line distribution between the two electrodes is shown;

FIG. 5a illustrates a top view of an alternative photodetector according to one implementation. FIG. 5b illustrates a top view of the photodetector of FIG. 5a in which electric field line distribution between the electrodes is shown;

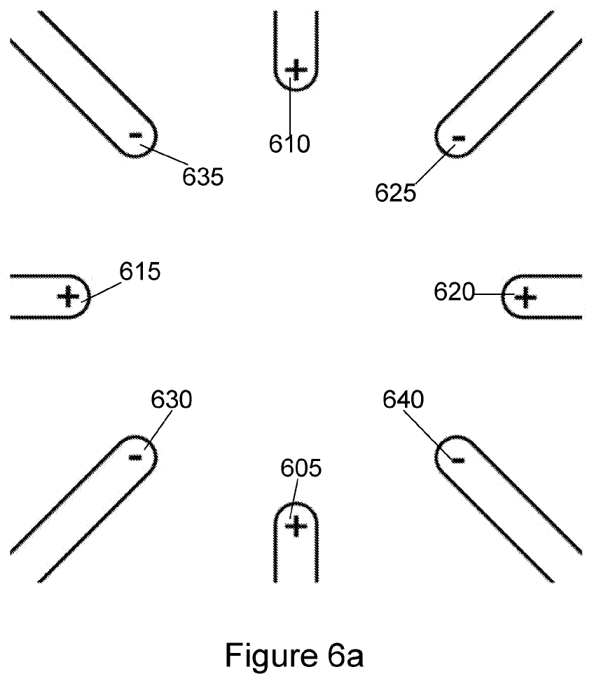

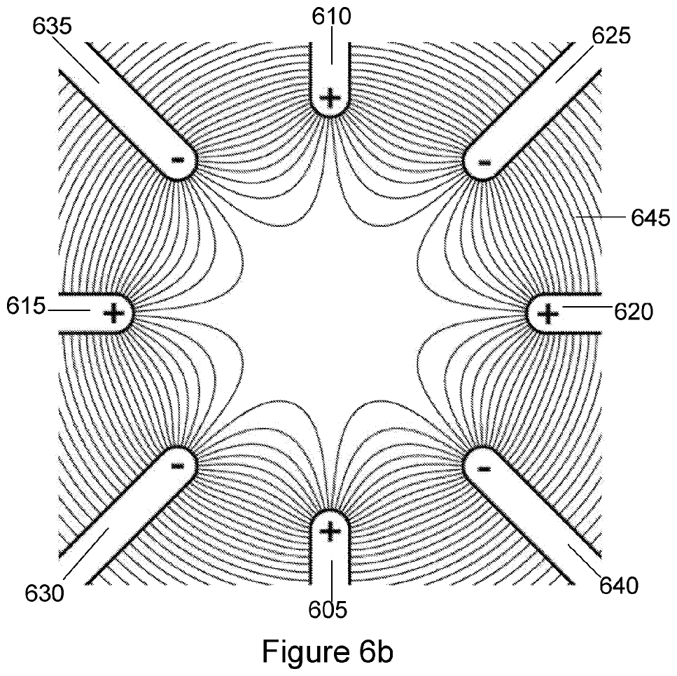

FIG. 6a illustrates a top view of an alternative photodetector according to one implementation. FIG. 6b illustrates a top view of the photodetector of FIG. 6a in which electric field line distribution between the electrodes is shown;

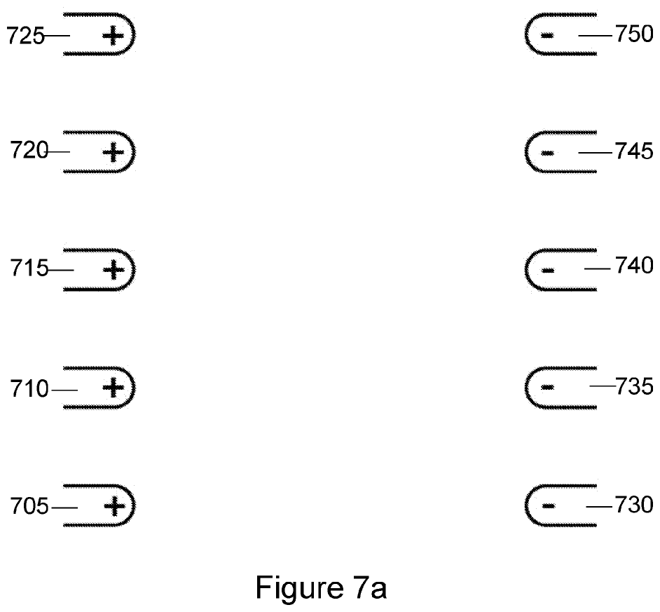

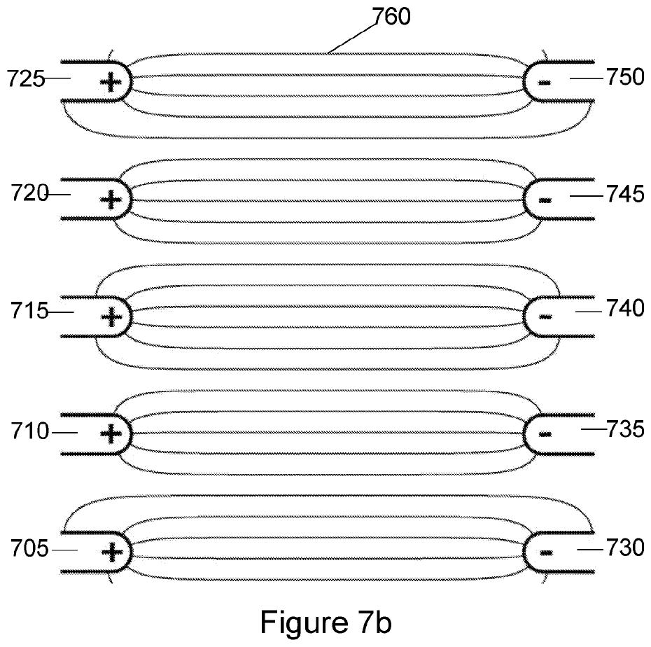

FIG. 7a illustrates a top view of an alternative photodetector according to one implementation. FIG. 7b illustrates a top view of the photodetector of FIG. 7a in which electric field line distribution between the electrodes is shown;

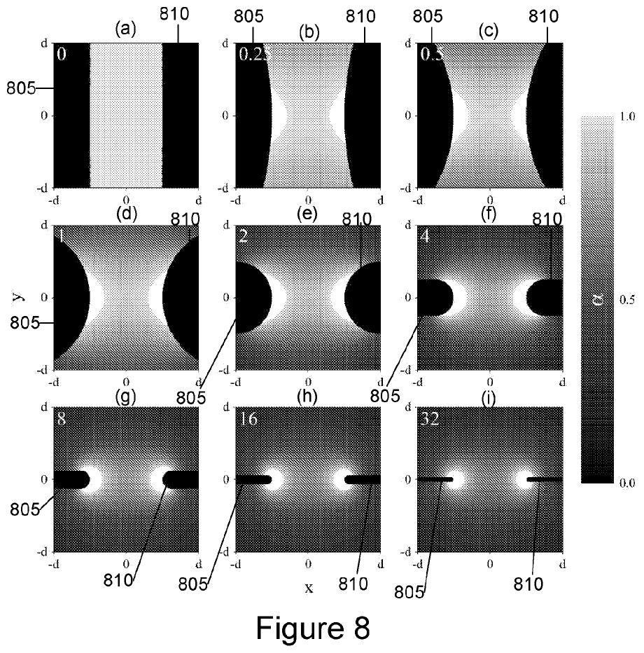

FIG. 8 is a plan profile of the field magnitude established between the electrodes of nine different electrode geometries, each of the same electrode separation, but of varying electrode radii R; and

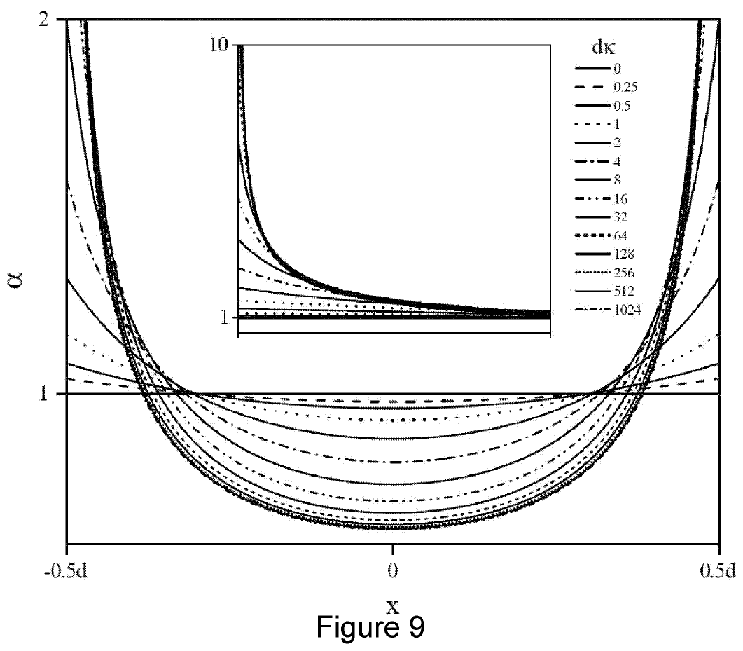

FIG. 9 illustrates field magnitudes along the line y=0 for nine different electrode geometries of varying relative curvatures in FIG. 8

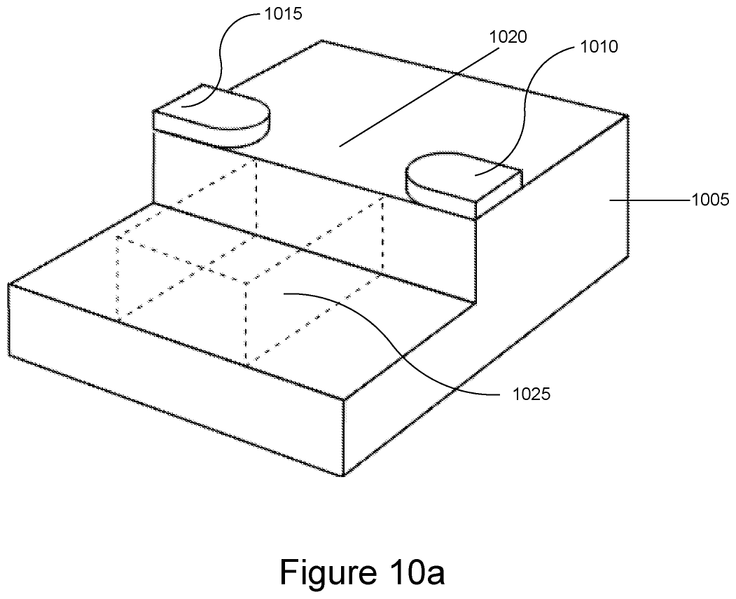

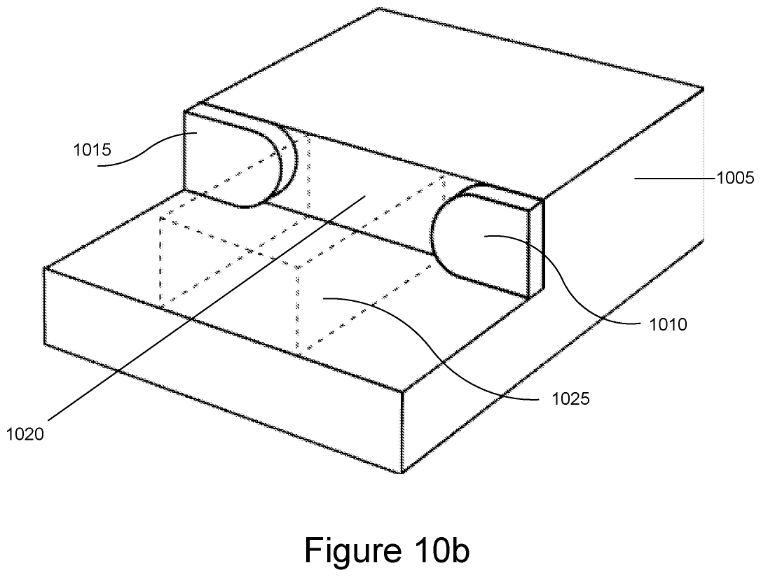

FIG. 10 (a) and FIG. 10 (b) illustrates a 3D figure of a device configured for integration with on-chip planar waveguides.

### DETAILED DESCRIPTION OF THE PREFERRED EMBODIMENTS

### General Device Structure in Alternative Implementations

FIG. 2 illustrates a three-dimensional view of a photodetector according to one embodiment or implementation. The photodetector includes a single absorption region (or absorption layer) 205. Two electrodes 210, 215 are disposed or formed on the absorption region spaced from one another. There is a (lateral) distance (or separation) 220 between the two electrodes 210, 215. The absorption region 205 includes a substantially un-doped material. In other words, the absorption region 205 includes an intrinsic material. In this embodiment, both electrodes 210, 215 have substantially the same or equivalent curvatures. When a bias (or an electrical bias) of sufficient magnitude is applied across electrodes 210, 215, due to the curvature of the electrodes and the separation between them, an electric field is established between them of the requisite magnitude for avalanche multiplication to occur near them. It will be appreciated that both the curvature and/or the distance 220 between the electrodes 210, 215 determines the breakdown voltage. Given that no doping is used in the absorption region, it is surprising that avalanche breakdown may be achieved by controlling the geometry (e.g. the curvature and/or electrode separation) of the electrodes.

FIG. 3a illustrates a top view of an alternative photodetector according to one embodiment or implementation. FIG. 3b illustrates a top view of the photodetector depicted in FIG. 3a, in which electric field line distribution between two electrodes is shown. Two electrodes 305, 310 are disposed on the absorption region spaced from one another. The curvature and/or shape of both electrodes 305 and 310 are not equivalent in this example, and are therefore referred to as being asymmetric. For example, the first electrode 305 has a predetermined curvature and the second electrode 310 has a different arrangement or shape compared to the first electrode 305. When a bias of sufficient magnitude is applied across the electrodes, an enhanced electric field is established near electrode 305 as indicated by the increased density of field lines (see FIG. 3b). This enhanced electric field may result in avalanche breakdown near the first electrode 305.

FIG. 4a illustrates a top view of an alternative photodetector according to one embodiment or implementation. FIG. 4b illustrates a top view of the photodetector of FIG. 4a in which electric field line distribution between two electrodes is shown. Two electrodes 405, 410 are disposed on the absorption region spaced from one another. In this embodiment, the curvature and/or shape of both electrodes 405, 410 are equivalent or substantially the same and are therefore referred to as being symmetric. When a bias of sufficient magnitude is applied across the electrodes, an enhanced electric field is established near electrode 415 near the curved electrodes 405, 410 (see FIG. 4b), as indicated by the increased density of field lines. This enhanced electric field may result in avalanche breakdown near the electrodes 405, 410.

FIG. 5a illustrates a top view of an alternative photodetector according to one embodiment or implementation. FIG. 5b illustrates a top view of the photodetector of FIG. 5a in which electric field line distribution between the electrodes is shown. Four electrodes 505, 510, 515, 520 are disposed on the absorption region spaced from one another. More electrodes are used in this example to increase the volume of the detection region. In one example, the curvature and/or shape of electrodes 505, 510, 515, 520 could be symmetric. In an alternative example, the curvature and/or shape of the electrodes 505, 510, 515, 520 could be different and therefore the electrodes 505, 510, 515, 520 may be asymmetric When a bias of sufficient magnitude is applied across electrodes 505, 510, 515, 520 an enhanced electric field is established near them as indicated by the increased density of field lines (see FIG. 5b). This enhanced electric field may result in avalanche breakdown near electrodes 505, 510, 515, 520.

FIG. 6a illustrates a top view of an alternative photodetector according to one embodiment or implementation. FIG. 6b illustrates a top view of the photodetector of FIG. 6a in which electric field line distribution between the electrodes is shown. In the implementation of FIG. 6a and FIG. 6b, eight electrodes 605, 610, 615, 620, 625, 630, 635, 640 are disposed on the absorption region spaced from one another. Like the implementation of FIG. 5, more electrodes are used in this example to increase the volume of the detection region. In one example, the curvature and/or shape of the electrodes 605, 610, 615, 620, 625, 630, 635, 640 are substantially the same and therefore the electrodes 605, 610, 615, 620, 625, 630, 635, 640 are symmetric. In an alternative example, the curvature and/or shape of the electrodes 605, 610, 615, 620, 625, 630, 635, 640 could be different and therefore the electrodes 605, 610, 615, 620, 625, 630, 635, 640 may be asymmetric. When a bias of sufficient magnitude is applied across electrodes 605, 610, 615, 620, 625, 630, 635, 640, an enhanced electric field is established near them as indicated by the increased density of field lines (see FIG. 6b). This enhanced electric field may result in avalanche breakdown near electrodes 605, 610, 615, 620, 625, 630, 635, 640.

FIG. 7a illustrates a top view of an alternative photodetector according to one embodiment or implementation. FIG. 7b illustrates a top view of the photodetector of FIG. 7a in which electric field line distribution between the electrodes is shown. Ten electrodes 705, 710, 715, 720, 725, 730, 735, 740, 745, 750 are disposed on the absorption region spaced from one another. The electrodes are organised, for example, in an arrangement suitable for wavelength spectrometry. Like the implementation of FIG. 6, more electrodes are used in this example to increase the volume of the detection region. In one example, the curvature and/or shape of the electrodes 705, 710, 715, 720, 725, 730, 735, 740, 745, 750 are substantially the same and therefore the electrodes are symmetric. In an alternative example, the curvature and/or shape of the electrodes 705, 710, 715, 720, 725, 730, 735, 740, 745, 750 could be different and therefore the electrodes may be asymmetric. When a bias of sufficient magnitude is applied across electrodes 715, 720, 725, 730, 735, 740, 745, 750, an enhanced electric field is established near them as indicated by the increased density of field lines (see FIG. 7b). This enhanced electric field may result in avalanche breakdown near electrodes 715, 720, 725, 730, 735, 740, 745, 750. This configuration may be used as part of a spectrometer when combined with a spectroscopic technique in which spatial separation of photons is obtained, such as refraction or diffraction. The spectral properties may be inferred from the position of photon incidence, which itself may be obtained from the electrode that collects the carriers.

FIG. 10 (a) and FIG. 10 (b) illustrate a three-dimensional view of a photodetector according to one embodiment or implementation. The photodetector device is configured for integration with on-chip planar waveguides 1025. The photodetector includes a single absorption region (or layer) 1005. Two electrodes 1010, 1015 are disposed on the absorption region spaced from one another. There is a distance 1020 between the two electrodes 1010, 1015. The absorption region 1005 includes a substantially un-doped material. The contacts or electrodes 1010, 1015 may be disposed on a step face (FIG. 10b) from a top surface, or on the top surface (FIG. 10a).

### Geometric Field Enhancement

We will now describe the theory behind the geometrical enhancement of the electric field that is here exploited for avalanche multiplication according to the implementations of the present disclosure. We will also discuss numerical simulation results.

According to Maxwell's equations, in the absence of a changing magnetic field the electric field E established between two electrodes is defined solely by the gradient of the electric potential ∇φ

$$\begin{matrix}E = - ∇ φ , where & ( 1 ) \\ ∇ φ = \hat{ι} \frac{\partial φ}{\partial x} + \hat{j} \frac{\partial ϕ}{\partial y} + \hat{k} \frac{\partial φ}{\partial z} , & ( 2 )\end{matrix}$$

a vector whose magnitude quantifies the spatial rate of change of the electric field at a given point, and whose direction specifies its steepest increase from that point.

From (1) and (2), it is not only evident that the bias applied across the electrodes affects the electric field established between them, but the very geometry (e.g. the curvature and/or shape and/or arrangement and/or electrode distance) of the electrodes themselves does too. Specifically, the electric field magnitude increases both with the applied bias and electrode curvature, but decreases with electrode separation.

The salient facet of the present disclosure is inherent in the exploitation of geometry, and in particular electrode curvature, rather than doping, to enhance the formation of an electric field of the requisite magnitude for avalanche breakdown to occur in a prescribed material: thereby providing the necessary amplification of current required for single-photon detection.

For a linear, isotropic, and homogeneous medium Gauss's law defines the electric field established by a given distribution of charge ρ

$$∇ \cdot E = \frac{ρ}{{ɛ}_{r} {ɛ}_{0}} , \qquad ( 3 )$$

where ∇·E is the divergence of the electric field

$$∇ \cdot E = \frac{\partial {E}_{x}}{\partial x} + \frac{\partial {E}_{y}}{\partial y} + \frac{\partial {E}_{z}}{\partial z} , \qquad ( 4 )$$

a scalar quantifying the extent to which the electric field diverges from a given point, εᵣ is relative permittivity of the medium, and ε₀ is the permittivity of vacuum.

In the case where the charge density is negligible, from (1) and (3)

εᵣε₀∇²φ=0 (5)

where ∇²φ is the Laplacian of the electric potential

$${∇}^{2} φ = \hat{ι} \frac{{\partial }^{2} φ}{\partial {x}^{2}} + \hat{j} \frac{{\partial }^{2} φ}{\partial {y}^{2}} + \hat{k} \frac{{\partial }^{2} φ}{\partial {z}^{2}} , \qquad ( 6 )$$

a scalar quantifying the divergence of the gradient of the electric field at a given point.

Both the bias V_{B} applied across the electrodes and the electrode geometry provide the necessary and sufficient boundary conditions to solve (5) for the electric potential cp over all space by the finite element method, before finally solving (1) for the electric field.

A selection of results of the 2D solutions to (5) and (1) are now presented. These are qualitatively similar to 3D simulations, which, for simplicity, are not shown. We define the field magnitude a as

$$α = ( \frac{d}{{V}_{B}} ) \vert E \vert , \qquad ( 7 )$$

where d is the electrode separation, V_{B} is the applied bias, and |E| is the electric field magnitude. It is important to note that the field magnitude is unitless.

FIG. 8 is a plan profile of the field magnitude established between the electrodes (805 and 810) of nine different electrode geometries, each of equivalent electrode separation, but of varying electrode radii R. The ratio of the electrode separation to electrode radius is here termed the relative curvature dκ, where κ=1/R is the curvature, and is varied in a binary geometric progression from 0.25 to 32. The parallel electrode case where dκ=0 is included for comparison. For the parallel electrode case (top left), at all points between the electrodes 805, 810 the field magnitude is unity (as no variation shown between the electrodes 805, 810). For all other geometries the electrodes 805, 810 are curved, in proximity to which regions of field enhancement (white regions), where the field magnitude is greater than unity, can clearly be observed.

It is known that for two parallel electrodes

$$\vert E \vert = \frac{{V}_{B}}{d} ,$$

in which case from (7) α=1. Accordingly, we define regions of field enhancement to be where α>1, and regions of field diminishment to be where α<1.

FIG. 9 illustrates field magnitudes along the line y=0 for nine different electrode geometries of varying relative curvatures in FIG. 8. The extent of field enhancement in the enhanced regions depicted in FIG. 8 is investigated in FIG. 9. In the parallel electrode case (top left of FIG. 8), the field magnitude (see dκ=0) is again confirmed to be unity at all points between the electrodes. For all other geometries the electrodes are curved, and exhibit enhanced regions in proximity to the electrodes where the field magnitude is greater than unity. The degree of field enhancement within the enhanced regions can be observed to increase both with increasing electrode proximity, and with increasing curvature. It is noteworthy that for the curved electrodes the electric field is diminished with increasing proximity to the electrode separation centre-point. The inset clearly shows the degree of field enhancement near the left electrode (as both electrodes have the exact same shape, the level of enhancement will be identical for the right electrode too), for relative curvatures dκ>256 the electric field is enhanced approaching the electrode interface by at least one order of magnitude. For all curved devices the enhanced region can be seen to extend at least 0.1d from each electrode.

It is clear both from FIGS. 8 and 9 that increasing the electrode curvature increases the field enhancement in their proximity. The degree of enhancement exponentially increases with increasing curvature, and rapidly tends to infinity. The bias V_{B} applied across the electrodes demands that an enhanced field is compensated for by a diminishment field elsewhere, but it is important to stress that the magnitude of the diminished field will not generally be zero—meaning photon-induced carriers created in the diminished region will be still be driven to the enhanced regions as intended.

### Example of Single-Photon Detection by Avalanche Breakdown

By operating a material at or above its breakdown field E_{b}—a method of operation referred to as Geiger mode operation—mobile charge carriers created by the internal photoelectric effect can gain enough kinetic energy from the electric field for collisions to be ionising: resulting in the creation of additional mobile charge carriers for which the process can repeat again. This mechanism, referred to as avalanche breakdown, is self-sustaining and produces a macroscopic mobilisation of charge from a single photon: resulting in a measurable detection signal. It will be appreciated that the present disclosure is not restricted to single-photon detection only.

### Breakdown Fields and Band Gaps

The following table details the breakdown fields of a number of different materials, sorted in order of increasing magnitude. The separation between two parallel electrodes required to facilitate avalanche breakdown at an applied bias of V_{B}=10 V is listed.

TABLE 1
Breakdown fields and band gaps.

| | E_{b} | | Band | Band |
|---|---|---|---|---|
| Material | (MVm⁻¹) | d (μm) | Gap (eV) | Gap (nm) |
| InSb | 0.1 | 100 | 0.17 | 7293 |
| In_{0.53}Ga_{0.47}As | 0.2 | 3.33 | 0.74 | 1675 |
| InAs | 0.2 | 2.5 | 0.35 | 3502 |
| GaSb | 4 | 2 | 0.72 | 1707 |
| Ge | 10 | 1 | 0.66* | 1875* |
| Si | 30 | 0.33 | 1.12* | 1107* |
| GaAs | 40 | 0.25 | 1.42 | 871 |
| C (Diamond) | 50 | 0.2 | 5.46* | 227* |
| InP | 50 | 0.2 | 1.34 | 922 |
| Al_{0.45}Ga_{0.55}As | 50 | 0.2 | 1.99 | 626 |
| GaP | 100 | 0.1 | 2.26* | 548* |
| AIN | 200 | 0.05 | 6.03 | 205 |
| BN | 400 | 0.03 | 6.1* | 203* |
| GaN | 500 | 0.02 | 3.28 | 378 |

Sorted in order of increasing magnitude, the breakdown fields for a selection of materials are listed. For each material the separation between two parallel electrodes required to facilitate avalanche breakdown at and applied bias of V_{B} = 10 V is listed along with the material's band gap in units of eV and nm.
*denotes the material has an indirect band gap.

### Geometric Field Enhancement Example

In one example only, for a GaAs device with an electrode separation of d=1 μm, to achieve breakdown at V_{B}=10 V from (7) a field magnitude of α≥4 is required, which in 2D is achieved approaching the electrodes by a relative curvature of dκ=64, corresponding to a radius of R=16 nm.

### Experimental Results

Devices have been fabricated from semi-insulating gallium arsenide (GaAs) and have been evidenced to be capable of undergoing avalanche breakdown at low voltages (for example, less than or equal to 10 V), and performing without amplification, room-temperature low-level light detection with response times below 100 ps.

### General Principles of the Implementations

We will now discuss the general principles of the operation of the photodetector device of the present disclosure. These principles are applicable to all the devices discussed above in FIGS. 2 to 8. Generally speaking, charge carriers are generated in the absorber region both by the absorption of incident photons, and by thermal excitation, with the former being desirable, and the latter undesirable. Absorbed photons will have energy equal to or greater than the absorber's band gap, where the absorber can be chosen to suit a particular application but with the proviso that unwanted thermally-generated carriers will be more problematic for smaller band-gap materials.

Generated carriers may initiate an avalanche breakdown, which will depend on:
1. The location of their production. Though dependent on scattering processes, carriers will tend to travel parallel to the electric field vector. If the carrier's path reaches an electrode without it encountering the avalanche region, it will not cause an avalanche.
2. The applied bias, and the absorber's breakdown field value. The shape of the electric field is independent of the applied voltage, but its magnitude is not. Larger voltages will give larger avalanche regions, allowing more generated carriers to contribute to the avalanche current. Similarly, a low breakdown field will give a smaller avalanche volume.
3. Applied electric or magnetic fields, whether using external or integrated devices, or fields such as would be generated by an absorber region which is magnetic or exhibits a spin-hall effect. Electric fields will perturb the absorber region electric field, and magnetic effects will deflect moving carriers.

If a carrier reaches an avalanche region during the above-breakdown part of the periodic bias (gated-Geiger mode operation), it will, through impact ionisation, generate a current additional to that which it contributes itself. If a carrier reaches the electrode without avalanching, this amplification effect is absent. Consequently, we can define from the electric field distribution a volume of the absorber in which carrier generation will lead to a measurable signal through avalanche multiplication. We designate this volume the detection region. The device should therefore be designed such that photons of the desired wavelength will be absorbed in the detection region; the characteristic absorption depth should be optimised to reduce to an acceptable degree the fraction of photons passing through this volume. The detection region is a subset of the avalanche region.

Thermally-generated carriers are the source of unwanted dark current, and are a limiting factor to device operation. An important observation is that, though all absorber materials will have a finite rate of thermal generation of carriers, only those created within the detection region will be amplified on reaching the device electrodes. In principle at least, it is therefore not necessary to provide electrical isolation for the device.

### Manufacturing or Realisation of the Disclosed Device

We will now discuss the manufacturing of the disclosed photodetector. The following comments are applicable to all the devices (in FIGS. 2 to 8) discussed in the present disclosure. The device may be made in many ways; its simplest configuration is the forming of two or more electrodes directly on the surface of the absorber material, with those electrodes connected to external control circuitry. The electrodes may be metal, or metal multilayers, but may also be semiconductors such as polysilicon or a layer or layers formed during the growth of the absorber; the necessary conditions are that the device is not significantly degraded by electrical resistance or intermediate insulating layers, and that the Fermi level in the conductor should align with the band structure of the absorber material at a point within the band-gap such that carrier injection from the contacts is not significant. The absorber (or the absorption region) itself is intended to be as free as possible of electrical carriers for reasons stated below, but the principle of geometric enhancement is also, but with lesser utility, applicable to Schottky-type contacts separated by a carrier-rich region. Cooling of the sample using a Peltier device may be practical, and cryogenic techniques may be necessary for detecting lower-energy photons or for very low photon fluxes.

Devices of the simplest type may be made by standard lithographic techniques using resist and the appropriate exposure and development. Generally speaking, techniques for doing this include:
1. Lift-off, in which the contact material, usually a metal or multilayer of metals, is deposited onto a lithographically-patterned surface. The resist is removed chemically, leaving the contact material only in the desired areas. Deposition here is best suited to a highly-directional technique such as resistive thermal or electron-beam evaporation, putting technical limitations on the choice of materials, but is often ideal for metals.
2. Etch-back, which involves the formation of a layer of contact material across the entire surface, followed by lithography and chemical- or plasma-etching of the unwanted material. Many techniques are suitable for layer deposition, including evaporative deposition, in-situ epitaxial growth such as molecular-beam or chemical epitaxies, or sputter-deposition.

Generally, the reflection of photons from the device surface will reduce detection efficiency. This may be addressed by techniques including anti-reflection coatings or layers. Similarly, a buried reflector stack may be used to reflect photons which would otherwise travel beyond the detection region.

It may be useful to tailor the electric-field profile in the device by patterning the absorber using the above (or other) processes. Etching of the absorber (or absorption region) prior to deposition could permit the recessing of contacts to optimise the detectable volume; the thickness of the detection region will be enhanced in this kind of structure. This may also be useful if surface recombination is a problem, as carriers would be drawn away from the surface by the field profile.

Recombination of carriers before avalanching results in a reduced responsivity and detection efficiency, and the time taken for carriers to traverse the device may limit its bandwidth. However, in the present device, the use of insulating or intrinsic semiconducting material improves both; the scarcity of free carriers strongly inhibits recombination and reduces the screening effects which limit electric field in conductors and doped semiconductors, leading to higher drift velocity and thus faster transit and higher bandwidth.

The dark current might be large enough that isolation of some kind is desirable. A way to achieve this would be to incorporate a wider-gap barrier layer below the detection region, minimising the bulk generation of carriers and/or blocking the progress of those carriers towards the surface. This may be improved further by mesa-etching the absorber such that as large an area as possible of the contacts lies on the barrier material. The removal by etching of a sacrificial buried layer, a thinning of the entire substrate, or using a free-standing thin film as the absorber may have a similar effect.

It will be appreciated that all doping polarities and/or voltage polarities mentioned above or shown in the figures could be reversed, the resulting devices still being in accordance with the present disclosure.

The skilled person will understand that in the preceding description and appended claims, positional terms such as ‘above’, ‘overlap’, ‘under’, ‘lateral’, ‘vertical’, etc. are made with reference to conceptual illustrations of a photodetector device, such as those showing standard cross-sectional perspectives and those shown in the appended drawings. These terms are used for ease of reference but are not intended to be of limiting nature. These terms are therefore to be understood as referring to a photodetector when in an orientation as shown in the accompanying drawings.

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1-24. (canceled)

25. A photodetector comprising:
at least one absorption region in which photons are absorbed;
a plurality of electrodes disposed on the at least one absorption region, wherein the plurality of electrodes are spaced apart from one another; and
wherein, in use, the geometry of at least one electrode of the plurality of electrodes is chosen to enhance the formation of an electric field of the requisite magnitude for avalanche multiplication to occur near the at least one electrode.

26. A photodetector according to claim 25, wherein the at least one absorption region comprises a predetermined material, and wherein the avalanche multiplication takes places in the predetermined material.

27. A photodetector according to claim 25, wherein the avalanche multiplication takes places near a surface between the at least one electrode and the at least one absorption region.

28. A photodetector according to claim 25, wherein the at least one absorption region comprises an avalanche region having a few or no dopants, and wherein the avalanche multiplication takes place in the avalanche region.

29. A photodetector according to claim 25, wherein the shape and arrangement of the at least one electrode are chosen to achieve said avalanche multiplication.

30. A photodetector according to claim 25, wherein a distance between at least two electrodes is selected to achieve said avalanche multiplication.

31. A photodetector according to claim 25, wherein a curvature of the at least one electrode is selected to achieve said avalanche multiplication.

32. A photodetector according to claim 25, wherein a relative curvature of the at least one electrode is varied to achieve said avalanche multiplication, wherein said relative curvature is derived from a ratio of a distance between at least two electrodes and a radius value of said at least one electrode.

33. A photodetector according to claim 25, wherein the degree of enhancement of the electric field magnitude increases with increasing curvature of said at least one electrode.

34. A photodetector according to claim 25, wherein, when a bias is applied between at least two electrodes, the electric field is enhanced in proximity to said at least two electrodes and the electric field is substantially diminished in a region between said at least two electrodes.

35. A photodetector according to claim 25, wherein said avalanche multiplication is achieved at less than or equal to about 10 V.

36. A photodetector according to claim 25, wherein the avalanche multiplication takes place at room temperature.

37. A photodetector according to claim 25, wherein the photodetector is a single-photon photodetector.

38. A photodetector according to claim 25, wherein at least some of the plurality of electrodes are symmetric or asymmetric and/or transparent.

39. A photodetector according to claim 25, wherein at least some of the plurality of electrodes are recessed below the level of the device surface.

40. A photodetector according to claim 25, wherein at least some of the plurality of electrodes are connected to control circuitry.

41. A photodetector according to claim 25, wherein the plurality of electrodes comprises any one or more of: a metal, metal multilayers, polysilicon, and a layer or layers formed during the growth of the absorption region.

42. A photodetector according to claim 25, further comprising anti-reflection coatings or anti-reflection layers.

43. A photodetector according to claim 25, further comprising:
a buried reflective layer to reflect photons back into the absorption region; or a detection region in the avalanche region and a barrier layer underneath the detection region, and wherein the barrier layer is a wider-gap barrier layer.

44. A method of manufacturing a photodetector, the method comprising:
forming at least one absorption region in which photons are absorbed;
depositing a plurality of electrodes disposed on the at least one absorption region, wherein the plurality of electrodes are spaced apart from one another; and
selecting the geometry of at least one electrode of the plurality of electrodes to enhance the formation of an electric field of the requisite magnitude for avalanche multiplication to occur near the at least one electrode.
